(19) United States
(12) Patent Application Publication
(10) Pub. No.: US 2024/0298432 A1
(43) Pub. Date: Sep. 5, 2024

(54) WATERCRAFT WITH LIQUID COOLED DISPLAY

(71) Applicant: Arc Boat Company, San Francisco, CA (US)

(72) Inventors: Audrey Gaither, San Francisco, CA (US); Prasad Deole, San Francisco, CA (US)

(21) Appl. No.: 18/592,942

(22) Filed: Mar. 1, 2024

Related U.S. Application Data
(60) Provisional application No. 63/487,732, filed on Mar. 1, 2023.

(51) Int. Cl. H05K 7/20; B63B 49/00; B63H 21/38

(52) U.S. Cl. CPC H05K 7/20981; B63B 49/00; B63H 21/383; H05K 7/20263; H05K 7/20272

(57) ABSTRACT

A watercraft comprising a display; and a liquid cooling system coupled to the display and configured to cool the display. The display has a brightness of at least 500 nits.

### CROSS-REFERENCE TO RELATED APPLICATIONS

This application claims the benefit of priority to U.S. Provisional Patent Application No. 63/487,732, filed Mar. 1, 2023, which is hereby incorporated by reference in its entirety.

### TECHNICAL FIELD

This disclosure relates to displays in watercraft (e.g., boats) and methods of using the same.

### BACKGROUND

Conventional displays for watercrafts have low brightness and are difficult to see in daylight. In addition, conventional displays for watercrafts are exposed to direct sunlight and easily overheat. Some conventional displays include a reflective coating to mitigate and reflect external heat from the sun, but such coatings on the display further reduce the ability to see the display in daylight.

### SUMMARY

The disclosure provides, in one aspect, a watercraft including a display and a liquid cooling system coupled to the display. The liquid cooling system is configured to cool the display. The display has a brightness of at least 500 nits.

In some embodiments, the display is a touch screen.

In some embodiments, the display is a capacitive touch screen.

In some embodiments, the display does not include a reflective coating.

In some embodiments, the brightness is at least 1,000 nits.

In some embodiments, the brightness is at least 1,500 nits.

In some embodiments, the display includes a circuit board, a housing, and a glass panel.

In some embodiments, the liquid cooling system includes a block, a channel formed in the block, and a liquid configured to flow through the channel.

In some embodiments, the channel forms a serpentine fluid flow path.

In some embodiments, the liquid cooling system further includes a cover, and wherein the cover is coupled to the block such that the cover encloses the channel in the block.

In some embodiments, an inlet is formed in the cover is in fluid communication with the channel and an outlet formed in the cover is in fluid communication with the channel.

In some embodiments, the block includes an aperture, and the display includes an electrical connection that extends through the aperture.

In some embodiments, the liquid cooling system further includes a pump configured to circulate the liquid through the channel.

In some embodiments, the liquid cooling system further includes a reservoir.

In some embodiments, the liquid cooling system is a closed-loop system.

In some embodiments, the liquid includes ethylene glycol and deionized water.

In some embodiments, the liquid cooling system further includes a heat exchanger configured to expel heat generated by the display to an environment.

In some embodiments, the watercraft further includes an electric drive and a battery electrically coupled to the electric drive; wherein the liquid cooling system is coupled to the electric drive and the battery and is configured to cool the electric drive and the battery.

In some embodiments, the watercraft further includes a dash, and a steering wheel extending from the dash, wherein the display is positioned on the dash.

Other aspects of the disclosure will become apparent by consideration of the detailed description and accompanying drawings.

### BRIEF DESCRIPTION OF THE DRAWINGS

These and other features, aspects, and advantages of the present technology will become better understood with regards to the following drawings. The accompanying figures and examples are provided by way of illustration and not by way of limitation.

FIG. 1 is a top view of a watercraft with a display.

FIG. 2 is a perspective view of the watercraft of FIG. 1, illustrating the display.

FIG. 3 is a schematic of a display coupled to a liquid cooling system.

FIG. 4 is a rear perspective view of a display and a liquid cooling system.

FIG. 5 is an enlarged partial rear view of the display and liquid cooling system of FIG. 4.

FIG. 6 is a perspective cross-sectional view of the display and liquid cooling system of FIG. 4.

FIG. 7 is a rear view of a cooling block with a cover of the liquid cooling system of FIG. 4.

FIG. 8 is a rear view of the cooling block of FIG. 7 with the cover removed.

FIG. 9 is a perspective view of a portion of the liquid cooling system of FIG. 4, illustrating a pump, a heat exchanger, and a fan.

Before any embodiments are explained in detail, it is to be understood that the invention is not limited in its application to the details of construction and the arrangement of components set forth in the following description or illustrated in the following drawings. The invention is capable of other embodiments and of being practiced or of being carried out in various ways.

### DETAILED DESCRIPTION

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing of the present disclosure. All publications, patent applications, patents and other references mentioned herein are incorporated by reference in their entirety. The materials, methods, and examples disclosed herein are illustrative only and not intended to be limiting.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “an” and “the” include plural references unless the context clearly dictates otherwise. The present disclosure also contemplates other embodiments “comprising,” “consisting of” and “consisting essentially of,” the embodiments or elements presented herein, whether explicitly set forth or not.

For the recitation of numeric ranges herein, each intervening number there between with the same degree of precision is explicitly contemplated. For example, for the range of 6-9, the numbers 7 and 8 are contemplated in addition to 6 and 9, and for the range 6.0-7.0, the number 6.0, 6.1, 6.2, 6.3, 6.4, 6.5, 6.6, 6.7, 6.8, 6.9, and 7.0 are explicitly contemplated.

The term “coupled,” as used herein, is defined as “connected,” although not necessarily directly, and not necessarily mechanically. The term coupled is to be understood to mean physically, magnetically, chemically, fluidly, electrically, or otherwise coupled, connected or linked and does not exclude the presence of intermediate elements between the coupled elements absent specific contrary language.

The term “nit” or “nits,” as used herein, refers to a unit of luminance based on candela per square meter.

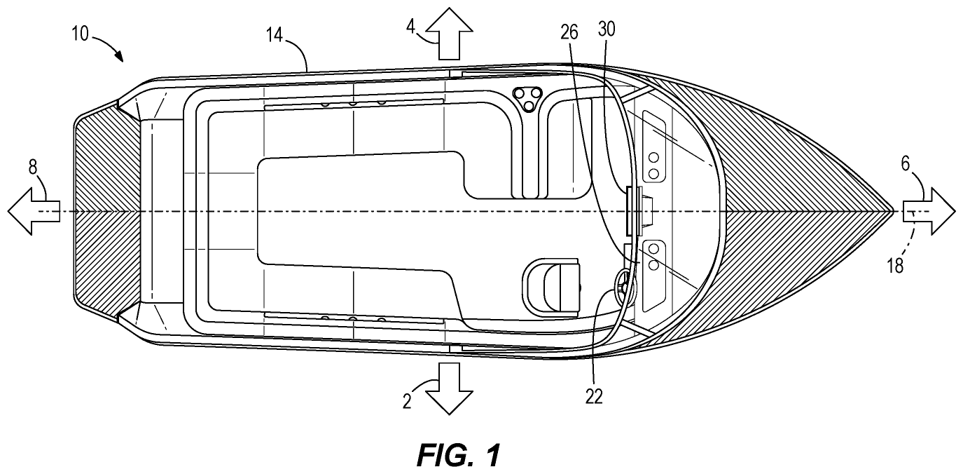

To facilitate the understanding of this disclosure, a number of marine terms are defined below. Terms defined herein have meanings as commonly understood by a person of ordinary skill in the areas relevant to the present disclosure. “Starboard” refers to the right-hand, or driver's, side of the watercraft. “Port” refers to the left-hand, or passenger's, side of the watercraft. “Bow” refers to the front of the watercraft. “Transom” and “stern” refer to the rear of the watercraft. The starboard 2, port 4, bow 6, and stern 8 directions are illustrated in FIG. 1 for reference.

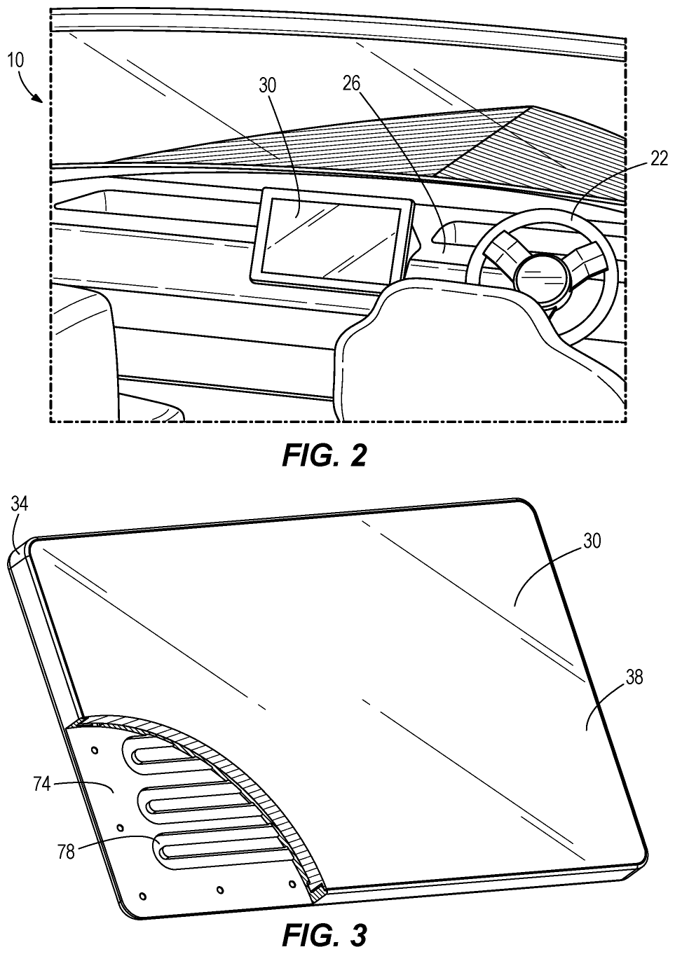

With reference to FIG. 1, a watercraft 10 includes a hull 14 that defines a center bow-stern axis 18. In some embodiments, the watercraft 10 is propelled through the water by a propeller that is rotationally driven by an electric drive. In some embodiments, the electric drive includes an electric motor (e.g., an induction motor, a synchronous motor, a brushless DC motor, a permanent magnet rotor, an interior permanent magnet motor, a surface permanent magnet motor, a reluctance motor, etc.) and a power converter (e.g., an inverter, a converter, etc.). In some embodiments, the watercraft includes a battery electrically coupled to the electric drive. The watercraft is steered through the water with adjustment of a rudder, for example, by a steering wheel 22. With reference to FIG. 2, the watercraft 10 includes a dash 26 (e.g., a front dashboard) and the steering wheel 22 extends from the dash 26.

With continued reference to FIG. 2, the watercraft 10 includes a display 30 (e.g., an electronic video display). In the illustrated embodiment, the display 30 is positioned on the dash 26. In some embodiments, the display 30 is centered on the dash 26 and intersected by the bow-stern axis 18. In some embodiments, the display 30 has a brightness of at least approximately 500 nits. In other words, the maximum brightness of the display is at least approximately 500 nits. In some embodiments, the maximum brightness is at least approximately 800 nits. In some embodiments, the maximum brightness is at least approximately 1,000 nits. In some embodiments, the maximum brightness is at least approximately 1,200 nits. In some embodiments, the maximum brightness is at least approximately 1,500 nits. In some embodiments, the maximum brightness is at least approximately 2,000 nits. In some embodiments, the maximum brightness is within a range of approximately 500 nits to approximately 800 nits. In some embodiments, the maximum brightness is within a range of approximately 800 nits to approximately 1,200 nits. In some embodiments, the maximum brightness is within a range of approximately 1,000 nits to approximately 2,000 nits. In some embodiments, the maximum brightness is within a range of approximately 500 nits to approximately 2,000 nits. In some embodiments, the brightness of the display is adjustable. In some embodiments, the brightness of the display is adjustable within a range from a lower threshold brightness (e.g., 0 nits, 10 nits, 20 nits, etc.) to the maximum brightness. In some embodiments, the brightness of the display is automatically adjusted based on the amount of light detected by a sensor.

Advantageously, the high brightness of the display 30 improves the visibility of the display 30 in daylight and direct sunlight. Operation and use of the watercraft 10 is often in bright daylight with the sun impacting an operator's ability to clearly see the display at lower brightness levels. Conventional displays do not operate at high brightness levels because conventional displays are thermally limited, and this is more pronounced for a display in a watercraft that operates outdoors in direct sunlight and is absorbing the incident solar energy.

With reference to FIG. 3, in the illustrated embodiment, the display 30 includes a circuit board, a housing 34, and a glass panel 38. In some embodiments, the display 30 is a touch screen capable of receiving user input via touch. In some embodiments, the display 30 is a capacitive touch screen. In some embodiments, the display 30 does not include a reflective coating. Eliminating use of a reflective coating on the display improves visibility of the display, but makes the display more absorbent to incident solar energy. In some embodiments, the display 30 does include a reflective coating, but the brightness of the display is high enough that the display remains bright enough even with the reduction in visibility from the reflective coating.

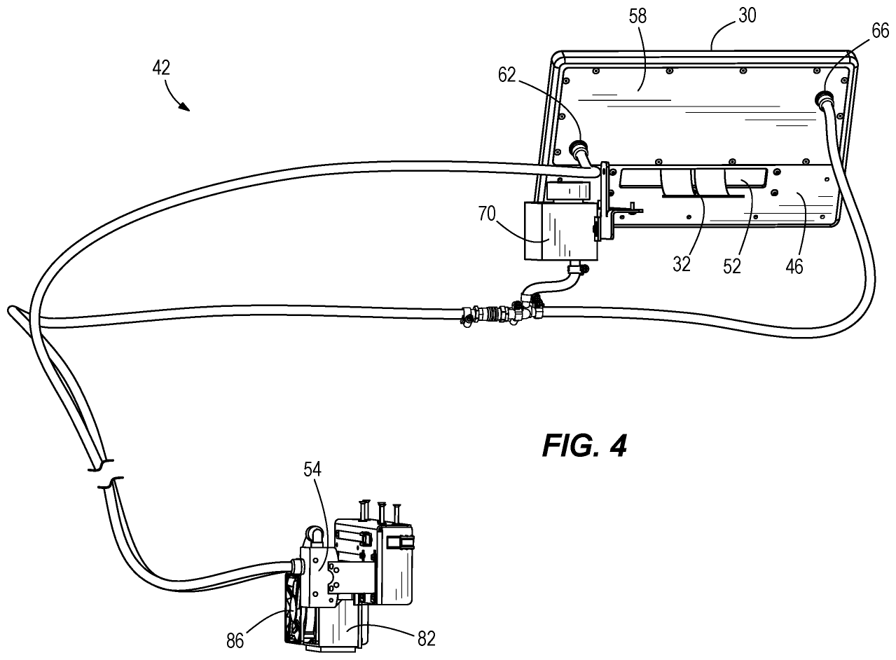

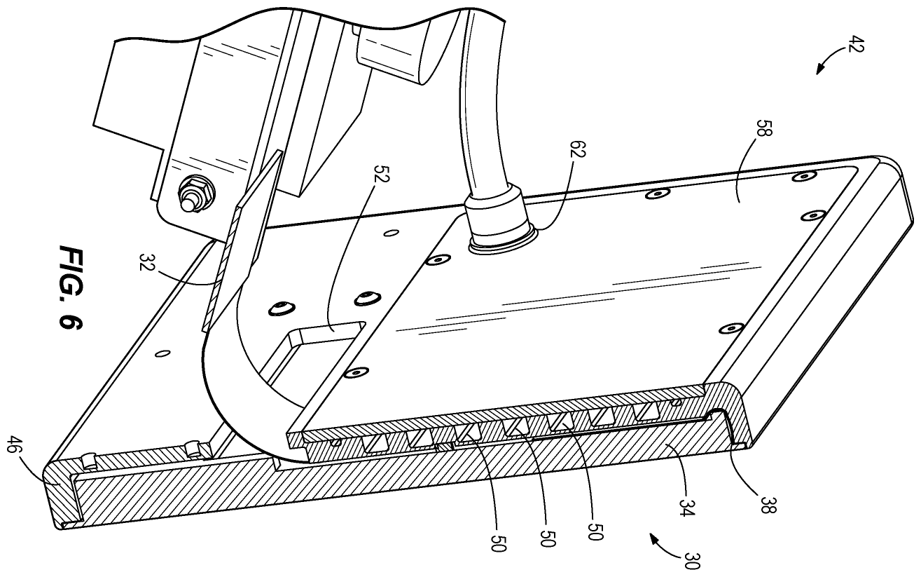

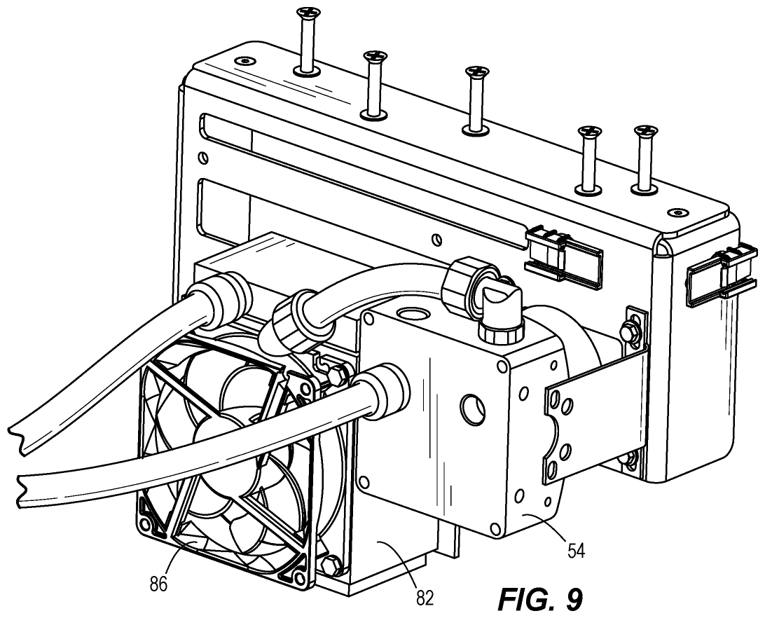

With reference to FIG. 4, the watercraft 10 further includes a liquid cooling system 42 coupled to the display 30 and configured to cool the display 30. In other words, the liquid cooling system 42 directly and actively cools the display 30. Actively cooling the display 30 advantageously permits the display 30 to operate at the higher brightness levels disclosed herein. In the illustrated embodiment, the liquid cooling system 42 includes a block 46, a channel 50 formed in the block 46, a liquid (e.g., a coolant, external water, etc.) configured to flow through the channel 50, and a pump 54 (FIG. 9) configured to circulate the liquid through the channel 50. With reference to FIGS. 6 and 8, in the illustrated embodiment, the channel 50 forms a serpentine fluid flow path.

In some embodiments, the liquid cooling system 42 is a closed-loop system (e.g., no external water is circulated). In some embodiments, the liquid cooling system is an open-loop system that circulates external water. In some embodiments, the circulating liquid (e.g., coolant, fluid) in the closed-loop system includes ethylene glycol and deionized water. As detailed herein, heat generated by the display 30 is transferred to the liquid circulating in the channel 50.

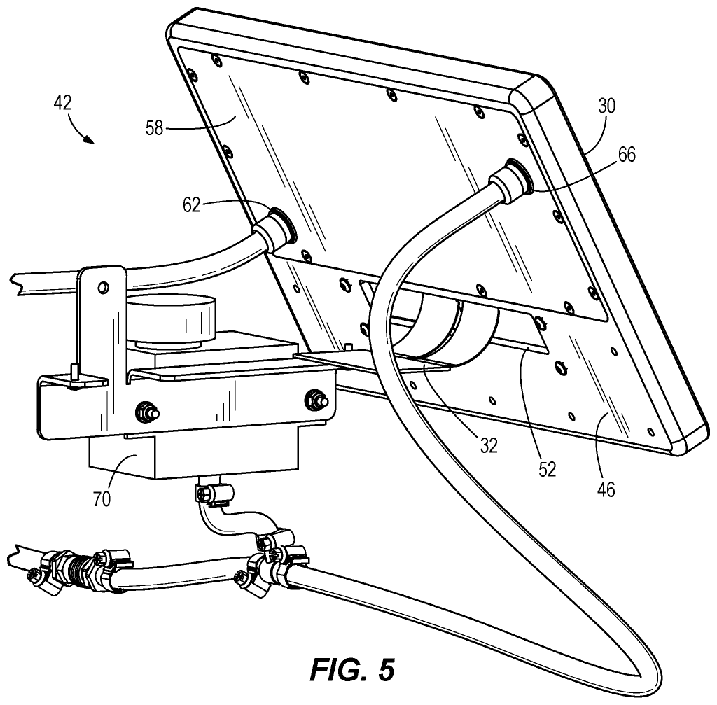

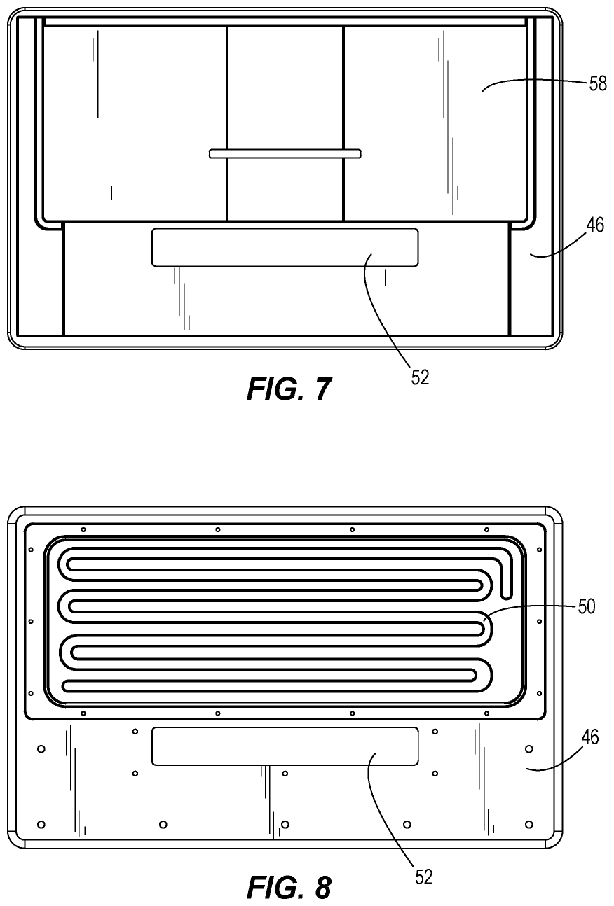

With reference to FIGS. 5-8, in some embodiments, the liquid cooling system 42 further includes a cover 58 removably coupled to the block 46. In the illustrated embodiment, the cover 58 is coupled to the block 46 such that the cover 58 encloses the channel 50 formed in the block 46. In other words, the cover 58 at least partially defines the fluid flow path through the block 46. In other embodiments, the block has the channel formed entirely within the block. In some embodiments, the block is additively manufactured (e.g., 3D printed) and/or braised and does not need a lid or cover to form the channel.

With reference to FIG. 3, in another embodiment, a block 74 of a liquid cooling system includes a channel 78 formed in the block 74, a liquid (e.g., a coolant, external water, etc.) configured to flow through the channel 78. In the illustrated embodiment, the channel 78 is at least partially enclosed by a portion of the display 30.

With continued reference to FIGS. 5-8, an inlet 62 is formed in the cover 58 and is in fluid communication with the channel 50, and an outlet 66 is formed in the cover 58 and is in fluid communication with the channel 50. In other embodiments, the inlet and outlet are formed in the block. In some embodiments, the liquid cooling system 42 includes a reservoir 70 configured to hold a supply of the liquid being circulated by the pump 54.

With continued reference to FIGS. 5-8. the block 46 includes an aperture 52 and the display 30 includes an electrical connection 32 that extends through the aperture 52. As such, the electrical connection 32 of the display 30 extends from the back of the display 30 while the back of the display 30 is also liquid cooled by the block 46. In some embodiments, a temperature sensor is included to detect a temperature of the display 30. In some embodiments, the temperature sensor is positioned between the block 46 and the display 30.

With reference to FIG. 9, the liquid cooling system 42 further includes a heat exchanger 82 configured to expel heat generated by the display 30 to an environment. In some embodiments, the environment is the external water that the watercraft 10 is positioned in. In some embodiments, the environment is the surrounding air and/or the air inside the hull that surrounds the thermal system. In some embodiments, the liquid cooling system 42 further includes a fan 86 configured to create an airflow across the heat exchanger 82.

In some embodiments, the liquid cooling system 42 is coupled to the electric drive and/or the battery and is configured to cool the electric drive and/or the battery. In other words, the liquid cooling system 42 that cools the display 30 also cools other heat-generating components (e.g., a motor, a battery, an inverter, etc.) on the watercraft 10.

In the illustrated embodiment, the watercraft 10 is a boat. In other embodiments, the watercraft is a fishing boat, a dingy boat, a deck boat, a bowrider boat, a catamaran boat, a cuddy cabin boat, a center console boat, a houseboat, a trawler boat, a cruiser boat, a game boat, a yacht, a personal watercraft boat, a water scooter, a jet-ski, a runabout boat, a jet boat, a wakeboard, a ski boat, a life boat, a pontoon boat, or any suitable motor boat, vessel, craft, or ship.

Although an example is illustrated with respect to an all-electric watercraft, the liquid-cooled display described herein can also be used in a conventional motorboat application (e.g., with a gasoline or diesel-powered engine), where the display is actively liquid cooled to meet brightness and other performance requirements.

Various features and advantages are set forth in the following claims.

What is claimed is:

1. A watercraft comprising:
a display; and
a liquid cooling system coupled to the display and configured to cool the display;
wherein the display has a brightness of at least 500 nits.

2. The watercraft of claim 1, wherein the display is a touch screen.

3. The watercraft of claim 2, wherein the display is a capacitive touch screen.

4. The watercraft of claim 1, wherein the display does not include a reflective coating.

5. The watercraft of claim 1, wherein the brightness is at least 1,000 nits.

6. The watercraft of claim 5, wherein the brightness is at least 1,500 nits.

7. The watercraft of claim 1, wherein the display includes a circuit board, a housing, and a glass panel.

8. The watercraft of claim 1, wherein the liquid cooling system includes a block, a channel formed in the block, and a liquid configured to flow through the channel.

9. The watercraft of claim 8, wherein the channel forms a serpentine fluid flow path.

10. The watercraft of claim 8, wherein the liquid cooling system further includes a cover, and wherein the cover is coupled to the block such that the cover encloses the channel in the block.

11. The watercraft of claim 10, wherein an inlet formed in the cover is in fluid communication with the channel and an outlet formed in the cover is in fluid communication with the channel.

12. The watercraft of claim 8, wherein the block includes an aperture and the display includes an electrical connection that extends through the aperture.

13. The watercraft of claim 8, wherein the liquid cooling system further includes a pump configured to circulate the liquid through the channel.

14. The watercraft of claim 13, wherein the liquid cooling system further includes a reservoir.

15. The watercraft of claim 8, wherein the liquid cooling system is a closed-loop system.

16. The watercraft of claim 12, wherein the liquid includes ethylene glycol and deionized water.

17. The watercraft of claim 1, wherein the liquid cooling system further includes a heat exchanger configured to expel heat generated by the display to an environment.

18. The watercraft of claim 1, further including an electric drive and a battery electrically coupled to the electric drive; wherein the liquid cooling system is coupled to the electric drive and the battery and is configured to cool the electric drive and the battery.

19. The watercraft of claim 1, further including a dash, and a steering wheel extending from the dash, wherein the display is positioned on the dash.
